(19) United States
(12) Patent Application Publication
(10) Pub. No.: US 2025/0380472 A1
(43) Pub. Date: Dec. 11, 2025

(54) HYBRID DIELECTRIC BAR

(71) Applicant: International Business Machines Corporation, Armonk, NY (US)

(72) Inventors: Minhaz Abedin, Delmar, NY (US); Ruilong Xie, Niskayuna, NY (US); Chen Zhang, Santa Clara, CA (US); Oleg Gluschenkov, Tannersville, NY (US)

(21) Appl. No.: 18/739,954

(22) Filed: Jun. 11, 2024

(51) Int. Cl. H01L 29/06; H01L 27/092; H01L 29/423; H01L 29/775

(52) U.S. Cl. CPC H10D 62/115; H10D 30/43; H10D 30/6735; H10D 84/853; H10D 62/121

(57) ABSTRACT

A semiconductor device is provided that includes a hybrid dielectric bar located between a PFET and an NFET and extending from a frontside of the device to the backside of the device. The hybrid dielectric bar includes an upper portion composed of a first dielectric structure and a lower portion composed of a second dielectric structure in which the second dielectric structure has a higher dielectric constant than the first dielectric structure.

### BACKGROUND

The present application relates to semiconductor technology, and more particularly to a semiconductor device including a hybrid dielectric bar located between a p-type field effect transistor (PFET) and an n-type field effect transistor (NFET) and extending from a frontside of the device to the backside of the device.

Backside power delivery refers to a novel technique where power supply lines are routed on the backside of a semiconductor chip or integrated circuit (IC), rather than the traditional frontside. Backside power delivery offers several advantages, including increased logic density and improved power and performance (better signal integrity, reduced noise and improved overall chip performance).

### SUMMARY

A semiconductor device is provided that includes a hybrid dielectric bar located between a PFET and an NFET and extending from a frontside of the device to the backside of the device. The hybrid dielectric bar includes an upper portion composed of a first dielectric structure and a lower portion composed of a second dielectric structure in which the second dielectric structure has a higher dielectric constant than the first dielectric structure. The presence of the hybrid dielectric bar on the backside of the device permits the formation of a VDD backside structure to be next to a VSS backside structure without shorting. Also, the presence of the hybrid dielectric bar on the backside of the device can provide an increase in decoupling capacitance between the VDD backside structure and the VSS backside structure, while reducing parasitic capacitance between source/drain regions and gate electrodes of the NFET and PFET.

In one aspect of the present application, the semiconductor device includes a hybrid dielectric bar present between a first transistor of a first conductivity type and a second transistor of a second conductivity type that is different from the first conductivity type. The hybrid dielectric bar includes an upper portion composed of a first dielectric structure having a first dielectric constant and a lower portion composed of a second dielectric structure having a second dielectric constant in which the second dielectric constant is greater than the first dielectric constant. The semiconductor device further includes a backside back-end-of-the-line (BEOL) structure electrically connected to a first device source/drain region of the first transistor and to a second device source/drain region of the second transistor. In this embodiment, the hybrid dielectric bar contacts the backside BEOL structure.

In another embodiment of the present application, the semiconductor device includes a first active device area including a first set of first transistors of a first conductivity type, a second active device area located adjacent to the first active device area and including a second set of first transistors of the first conductivity type, a third active device area located adjacent to the second active device area and including a first set of second transistors of a second conductivity type that is different from the first conductivity type, and a fourth active device area located adjacent to the third active device area and including a second set of second transistors of the second conductivity type. The semiconductor device of this embodiment further includes a hybrid dielectric bar present between the second set of first transistors and the first set of second transistors. The hybrid dielectric bar includes an upper portion composed of a first dielectric structure having a first dielectric constant and a lower portion composed of a second dielectric structure having a second dielectric constant in which the second dielectric constant is greater than the first dielectric constant. The semiconductor device further includes a first gate cut pillar located between the first set of first transistors and the second set of first transistors, and a second gate cut pillar located between the first set of second transistors and the second set of second transistors in which the first gate cut pillar and the second gate cut pillar are composed entirely of the first dielectric structure.

### BRIEF DESCRIPTION OF THE DRAWINGS

FIG. 1 is a top down view of a device layout that can be employed in accordance with an embodiment of the present application.

FIGS. 2A-2C are cross sectional views of an exemplary structure through cuts A-A, B-B and C-C respectively of FIG. 1 that can be used in accordance with an embodiment of the present application, the exemplary structure including at least one first transistor of a first conductivity type and at least one second transistor of a second conductivity type, different from the first conductivity type, located adjacent to each other and located on a surface of a substrate.

FIGS. 3A-3C are cross sectional views of the exemplary structure of FIGS. 2A-2C, respectively, after performing a gate cut process in which gate cut openings are formed.

FIGS. 4A-4C are cross sectional views of the exemplary structure of FIGS. 3A-3C, respectively, after deepening one of the gate cut openings to provide a dielectric bar opening that is between the at least one first transistor and the at least one second transistor, the dielectric bar opening extending into a semiconductor base layer of the substrate.

FIGS. 5A-5C are cross sectional views of the exemplary structure of FIGS. 4A-4C, respectively, after filling each gate cut opening and the dielectric bar opening with a first dielectric structure having a first dielectric constant.

FIGS. 6A-6C are cross sectional views of the exemplary structure of FIGS. 5A-5C, respectively, after forming a gate connector region above the first dielectric structure filled dielectric bar opening (i.e., dielectric bar).

FIGS. 7A-7C are cross sectional views of the exemplary structure of FIGS. 6A-6C, respectively, after forming a middle-of-the-line (MOL) level, a frontside back-end-of-the-line (BEOL) structure, and a carrier wafer.

FIGS. 8A-8C are cross sectional views of the exemplary structure of FIGS. 7A-7C, respectively, after flipping the wafer and removing the semiconductor base layer of the substrate to physically expose an etch stop layer of the substrate and a portion of the dielectric bar.

FIGS. 9A-9C are cross sectional views of the exemplary structure of FIGS. 8A-8C, respectively, after removing the etch stop layer and a semiconductor device layer of the substrate, and forming a backside interlayer dielectric (ILD) layer.

FIGS. 10A-10C are cross sectional views of the exemplary structure of FIGS. 9A-9C, respectively, after recessing a lower portion of dielectric bar to provide a backside bar opening.

FIGS. 11A-11C are cross sectional views of the exemplary structure of FIGS. 10A-10C, respectively, after forming a second dielectric structure having a second dielectric constant that is greater than the first dielectric constant in the backside bar opening.

FIGS. 12A-12C are cross sectional views of the exemplary structure of FIGS. 11A-11C, respectively, after patterning the backside ILD layer to provide a trench opening and backside contact vias.

FIGS. 13A-13C are cross sectional views of the exemplary structure of FIGS. 12A-12C, respectively, after physically exposing a first device source/drain region of the at least one first transistor and a second device source/drain region of the at least one second transistor, and forming a backside contact conductor material layer.

FIGS. 14A-14C are cross sectional views of the exemplary structure of FIGS. 13A-13C, respectively, after recessing the backside contact conductor material layer and forming a backside power rail material layer.

FIGS. 15A-15C are cross sectional views of the exemplary structure of FIGS. 13A-13C, respectively, after forming a backside BEOL structure on the backside contact conductor material layer.

FIGS. 16A-16C are cross sectional views of the exemplary structure of FIGS. 14A-14C, respectively, after forming a backside BEOL structure on the backside power rail material layer.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. In the embodiment described in the present application, the transistor is a nanosheet transistor. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology. Although nanosheet transistors are described in this application, this application is not limited to nanosheet transistors. Instead, the present application can be used for finFETs, nanowire FETs, planar FETs, fork sheet transistors, stacked FETs or any combination of such FETs including nanosheet transistors.

In the present application, the semiconductor device includes a frontside and a backside. The frontside includes a side of the device that includes at least one transistor, frontside contact structures, and a frontside BEOL structure. The backside of the semiconductor device is the side of the device that is opposite the frontside. The backside includes backside contact structures, and a backside BEOL structure. The backside BEOL structure can be a backside power distribution network that is capable of delivering power to the transistor through the backside of the semiconductor device.

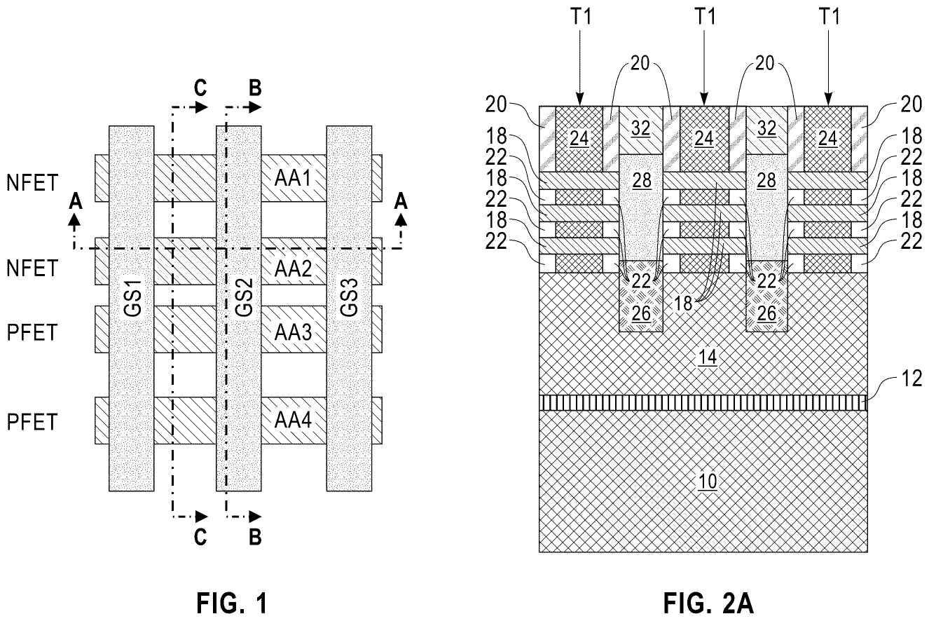

Referring first to FIG. 1, there is illustrated a device layout that can be employed in accordance with an embodiment of the present application. The illustrated device layout includes four active device areas, AA1, AA2, AA3 and AA4. AA1 is a first active device area in which NFETs can be formed, AA2 is a second active device area in which other NFETs can be formed, AA3 is a third active device area in which PFETs can be formed, and AA4 is a fourth active device area in which other PFETs can be formed. In FIG. 1, three gate structures, GS1, GS2 and GS3 are shown by way of one example. The present application is not limited to using three gate structures. The gate structures run parallel to each other and perpendicular to each of the active device areas. Although FIG. 1 specifically illustrates NFETs in AA1 and AA2, and PFETs in AA3 and AA4, the present application works when PFETs are formed in AA1 and AA2, and NFETS are formed in AA3 and AA4. Notably, AA1 and AA2 are active device areas in which first transistors of a first conductivity type are formed, while AA3 and AA4 are active device areas in which second transistors of a second conductivity type are formed. In the present application, the second conductivity type is of a different conductivity than the first conductivity type. It is noted that AA1 and AA4 are not required and can be omitted in some embodiments of the present application.

FIG. 1 also includes three different cuts, namely cut A-A, cut B-B, and cut C-C that will be used throughout the remaining drawings of the present application. Cut A-A is a cut that runs in a length wise direction through a portion of AA2. Cut B-B is a cut that runs in a length wise direction through a portion of the second gate structure GS2 and it passes through each of AA1, AA2, AA3 and AA4. Cut C-C is a cut that runs in a length wise direction between the first gate structure, GS1, and the second gate structure, G2 and it passes through each of AA1, AA2, AA3 and AA4. Notably, cut C-C will show the source/drain areas of the transistors of the present application.

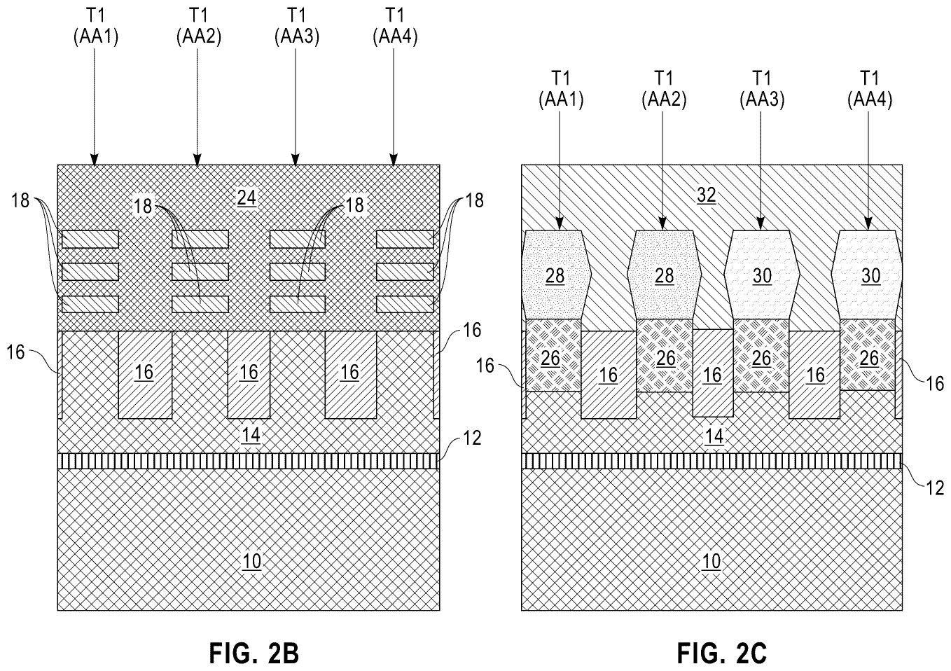

Referring now to FIGS. 2A-2C, there are illustrated an exemplary structure through cuts A-A, B-B and C-C respectively of FIG. 1 that can be used in accordance with an embodiment of the present application. The exemplary structure illustrated in FIGS. 2A-2C includes at least one first transistor T1 of a first conductivity type and at least one second transistor T2 of a second conductivity type, different from the first conductivity type located adjacent to each other and on a surface of a substrate. In the illustrated embodiment, there is a first active device area that includes a first set of the first transistors T1, a second active device area adjacent to the first active device area that includes a second set of the first transistors T1, a third active device area adjacent to the second active device area and including a first set of second transistors T2, and a fourth active device area adjacent to the third active device area and including a second set of second transistors T2. In one embodiment of the present application, the first transistors T1 can be NFET, and the second transistors T2 are PFETs. In another embodiment of the present application, the first transistors T1 can be PFETs and the second transistors T2 can be NFETs. The exemplary semiconductor structure also includes a shallow trench isolation structure 16 located between each of the active device areas and in an upper portion of the substrate (i.e., each shallow trench isolation structure is located in a semiconductor device layer 14 of the substrate). In the present application, the first transistors and second transistors are illustrated as nanosheet transistors.

Each first transistor T1 can include a vertical nanosheet stack of spaced apart semiconductor channel material nanosheets 18, a gate structure 24, and first device source/drain regions 28. Each second transistor T2 can include a vertical nanosheet stack of spaced apart semiconductor channel material nanosheets 18, gate structure 24, and second device source/drain regions 30. Both the first and second transistors can include gate spacers 20 and inner spacers 22.

The exemplary structure further includes a backside source/drain contact placeholder structure 26 located beneath each of the first device source/drain regions 28 and the second device source/drain regions 30. Each backside source/drain contact placeholder structure 26 is embedded in an upper portion (i.e., the semiconductor device layer 14) of the substrate. A first frontside ILD layer 32 is also present which embeds the first device source/drain regions 28 and the second device source/drain regions 30. Notably, the first frontside ILD layer 32 is located on top of, and adjacent to, each of the first device source/drain regions 28 and the second device source/drain regions 30, and the first frontside ILD layer 32 contacts a surface of each shallow trench isolation structure 16.

The various elements/components of the exemplary semiconductor structure shown in FIGS. 2A-2C will now be described in greater detail. In addition to the semiconductor device layer 14 mentioned above, the substrate that can be employed in the present application can also include a semiconductor base layer 10 and an etch stop layer 12. As is shown, the etch stop layer 12 is sandwiched between the semiconductor base layer 10 and the semiconductor device layer 14. Embodiments are contemplated in which the semiconductor base layer 10 and/or etch stop layer 12 are omitted.

The semiconductor base layer 10 is composed of a first semiconductor material, and the semiconductor device layer 14 is composed of a second semiconductor material. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the semiconductor device layer 14 can be compositionally the same as, or compositionally different from, the first semiconductor material that provides the semiconductor base layer 10. In some embodiments of the present application, the etch stop layer 12 can be composed of a dielectric material such as, for example, silicon dioxide and/or boron nitride. In other embodiments of the present application, the etch stop layer 12 is composed of a third semiconductor material that is compositionally different from the first semiconductor material that provides the semiconductor base layer 10 and the second semiconductor material that provides the semiconductor device layer 14. In one example, the semiconductor base layer 10 is composed of silicon, the etch stop layer 12 is composed of silicon dioxide, and the semiconductor device layer 14 is composed of silicon. In another example, the semiconductor base layer 10 is composed of silicon, the etch stop layer 12 is composed of silicon germanium, and the semiconductor device layer 14 is composed of silicon.

Each shallow trench isolation structure 16 can include a trench dielectric liner and a trench dielectric material. In some embodiments, the trench dielectric liner can be omitted. When the trench dielectric liner is present, it is located along a sidewall and a bottom surface of the trench dielectric material. In one example, the trench dielectric liner is composed of SiN, and the trench dielectric material is composed of silicon dioxide. In some embodiments, each shallow trench isolation structure 16 can have a topmost surface that is substantially coplanar with a topmost surface of the substrate (e.g., the semiconductor device layer 14). In other embodiments, each shallow trench isolation structure 16 can have a topmost surface that is vertically offset (i.e., higher or lower) than a topmost surface of the substrate (e.g., the semiconductor device layer 14).

Each semiconductor channel material nanosheet 18 is composed of a fourth semiconductor material. The fourth semiconductor material that provides each of the semiconductor channel material nanosheets 18 can be compositionally the same as, or compositionally different from, the second semiconductor material that provides the semiconductor device layer 14. In some embodiments, the fourth semiconductor material that provides each semiconductor channel material nanosheet 18 provides high channel mobility for NFET devices. In other embodiments, the fourth semiconductor material that provides each semiconductor channel material nanosheets 18 provides high channel mobility for PFET devices. Although the present application describes and illustrates that the semiconductor channel material nanosheets 18 in each of the vertical nanosheet stacks for the first transistors T1 and the second transistors T2 are composed of a compositionally same semiconductor material (i.e., the fourth semiconductor material), it is possible to design the vertical nanosheet stack such that the semiconductor channel material nanosheets 18 for the first transistors T1 are compositionally different from the semiconductor channel material nanosheets 18 for the second transistors T2. In the present application, the number of semiconductor material nanosheets 18 in a given nanosheet stack is at least 2. Although the present application describes and illustrates that the number of semiconductor channel material nanosheets 18 in each vertical nanosheet stack is the same, it is possible to have different number of semiconductor channel material nanosheets 18 in the vertical nanosheet stacks.

The gate spacer 20 and the inner spacer 22 are composed of a compositionally same or different spacer dielectric material. The dielectric spacer material can include, but is not limited to, silicon dioxide, SiN, SiBCN, SiOCN or SiOC. In the present application, the gate spacer 20 is located along a sidewall of the gate structure 24 and the inner spacers 22 are located beneath each of the semiconductor channel material nanosheets 18 present in the vertical nanosheet stacks.

The gate structure 24 includes a gate dielectric material and a gate electrode, both of which are not separately shown, but intended to be within the region defined by the gate structure 24. As is known to those skilled in the art, a gate dielectric material directly contacts a physically exposed surface(s) of the semiconductor channel region, and a gate electrode is formed on the gate dielectric material. The gate dielectric material has a dielectric constant of 4.0 or greater. All dielectric constants mentioned herein are relative to a vacuum unless otherwise noted. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg). The gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co).

Each backside source/drain contact placeholder structure 26 is composed of a fifth semiconductor material. The fifth semiconductor material is compositionally different from the second semiconductor material that provides the semiconductor device layer 14. Each backside source/drain contact placeholder structure 26 has a topmost surface that is substantially coplanar with a topmost surface of the semiconductor device layer 14. In some embodiments (not illustrated), a semiconductor buffer layer can be formed directly on top of the backside source/drain contact placeholder structure 26. When present, the semiconductor buffer layer is composed of a semiconductor material. The presence of the semiconductor buffer layer facilities epitaxial growth of the first device source/drain regions 28 and the second device source/drain regions 30. The semiconductor buffer layer is generally located above the topmost surface of the substrate (e.g., the topmost surface of the semiconductor device layer 14), but not above a bottommost surface of the bottommost semiconductor channel material nanosheet of each vertical nanosheet stack.

Each source/drain region (e.g., the first device source/drain regions 28 and the second device source/drain regions 30) is composed of a semiconductor material and a dopant. The dopant can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each source/drain region (e.g., the first device source/drain regions 28 and the second device source/drain regions 30) can have a dopant concentration of from 4×10²⁰ atoms/cm³ to 3×10²¹ atoms/cm³.

In the specific embodiment illustrated, each first device source/drain region 28 is composed of a sixth semiconductor material and a first dopant, and each second device source/drain region 30 is composed of a seventh semiconductor material and a second dopant in which the second dopant is of an opposite conductivity type than the first dopant. In the illustrated embodiment, the sixth semiconductor material can be compositionally the same as, or compositionally different from, the seventh semiconductor material.

The first frontside ILD layer 32 is composed of ILD material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that can have a dielectric constant of 7.0 or less, typically the low k dielectric materials have a dielectric constant of less than 4.0.

The exemplary semiconductor structure illustrated in FIGS. 2A-2C can be formed utilizing any well-known nanosheet transistor device fabrication process in which backside processing will be subsequently performed. The nanosheet transistor device fabrication process can include various deposition and patterning steps. The nanosheet transistor device fabrication process can include the formation of a sacrificial gate structure (not shown) to be used as an etch mask in defining a material stack of alternating sacrificial semiconductor material nanosheets (not shown) and semiconductor channel material nanosheet 18, removing each of the sacrificial semiconductor material nanosheets after defining the material stack and replacing the sacrificial gate structure with gate structure 24. In the present application, the various semiconductor materials can be formed by chemical vapor deposition (CVD), plasma enhanced chemical vapor deposition (PECVD) or epitaxial growth.

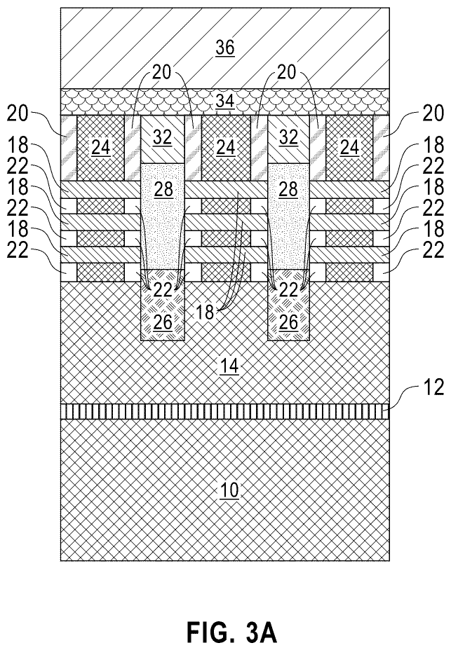

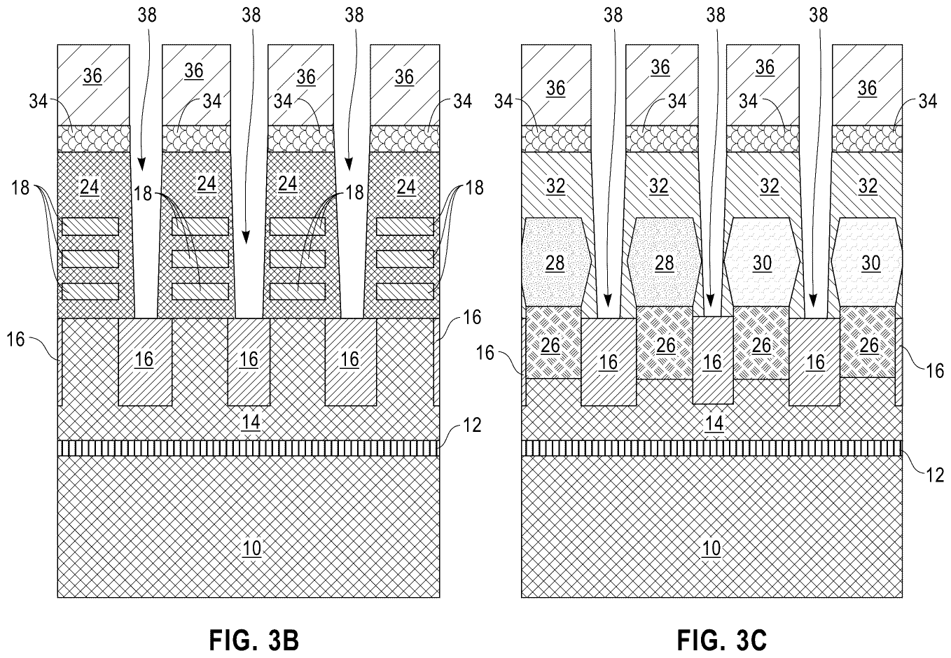

Referring now to FIGS. 3A-3C, there are illustrated the exemplary structure of FIGS. 2A-2C, respectively, after performing a gate cut process in which gate cut openings 38 are formed. Each gate opening 38 is formed through the gate structure 24 and the first frontside ILD layer 32 and lands on a surface of one of the shallow trench isolation structures 16 that is located between the active device areas. In FIG. 3B, the gate structure 24 is cut such that at this point of the present application independent gate structures 24 are formed in the different active device areas. The gate cut process includes forming a first masking layer 34 and a second masking layer 36 on the exemplary semiconductor structure illustrated in FIGS. 2A-2C. The first masking layer 34 can be formed by a first deposition process, while the second masking layer 36 can be formed by a second deposition process. The first and second deposition processes can include CVD, PECVD, physical vapor deposition (PVD) or spin-on coating. The first deposition process can be of same type as, or a different type than, the second deposition process. The first masking layer 34 is composed of a first masking material, while the second masking layer 36 is composed of a second masking material that is compositionally different from the first masking material. In one example, the first masking material is a hard mask material (i.e., silicon dioxide, silicon nitride or silicon oxynitride), and the second masking material is an organic planarization material. The gate cut process continues by lithographically patterning the first masking layer 34 and the second masking layer 36. Lithographic patterning includes forming a photoresist material on a layer/multilayered stack that needs to be patterned, exposing the as deposited photoresist material to a desired pattern of irradiation, developing the photoresist material and transferring the pattern from the developed photoresist material into the layer/multilayered stack that needs to be patterned, the transferring of the pattern can include one or more etching processes. The one or more etching processes can include dry etching and/or wet etching. Dry etching can include reactive ion etching (RIE), plasma etching or ion beam etching. Wet etching can include the use of a chemical etchant that is selective in removing physically exposed portions of the layer/multilayered stack that needs to be patterned. The photoresist material is removed after the pattern transfer process utilizing a material removal process that is selective in removing the photoresist material. In this part of the present application, the lithographic pattern provides openings that extend through the first masking layer 34 and the second masking layer 36. The openings in the first masking layer 34 and the second masking layer 36 coincide with the location in which gate cut openings 38 will be subsequently formed. After lithographically patterning the first masking layer 34 and the second masking layer 36, an etch (such as, for example, RIE) is used to transfer the pattern (i.e., openings) that are present in the first masking layer 34 and the second masking layer 36 into the exemplary semiconductor structure as shown in FIGS. 3A-3C.

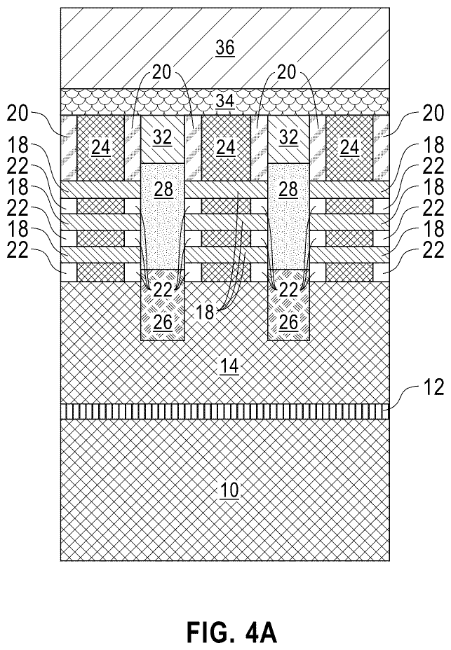

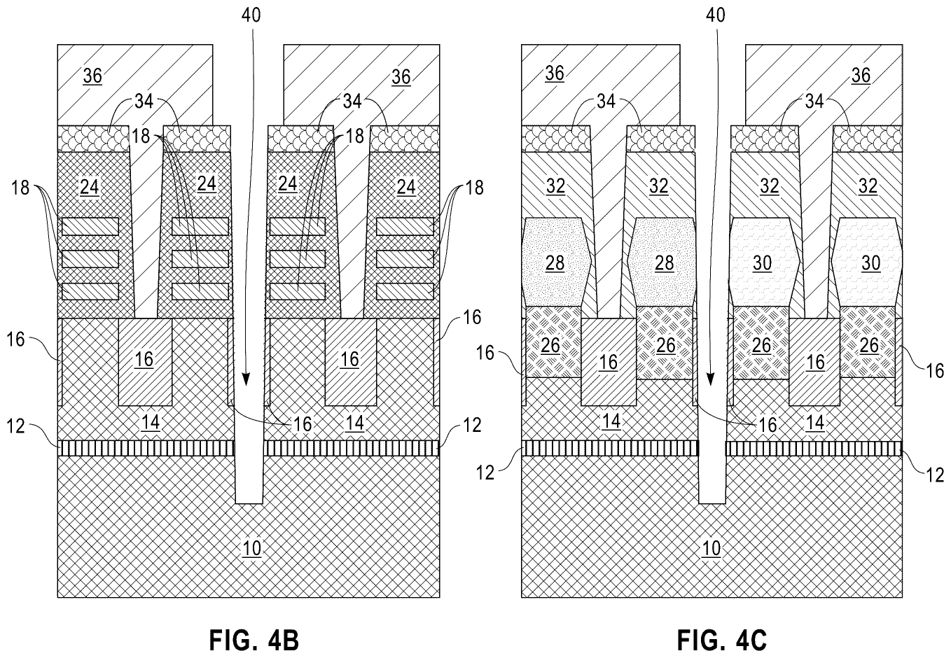

Referring now to FIGS. 4A-4C, there are illustrated the exemplary structure of FIGS. 3A-3C, respectively, after deepening one of the gate cut openings 38 to provide a dielectric bar opening 40 that is between the at least one first transistor T1 and the at least one second transistor T2, the dielectric bar opening 40 extends into semiconductor base layer 10 of the substrate. In the present application, the dielectric bar opening 40 needs to extend beneath the depth of the shallow trench isolation structures 16. The step of deepening one of the gate cut openings 38 includes redepositing the second masking layer 36 in each of the gate cut openings 38, lithographically patterning the second masking layer 36 to include a bar opening that is located between the first transistor T1 and second transistor T2, and then transferring the bar opening into the underlying semiconductor structure by etching (e.g., RIE). The etching removes the second masking layer 36 that is redeposited in the gate cut opening 38 that is located between the first transistor T1 and second transistor T2 and continues through the shallow trench isolation structure 16, the semiconductor device layer 14 and the etch stop layer 12, stopping on a sub-surface (i.e., a surface between a topmost surface and a bottom surface of a layer/structure) of the semiconductor base layer 10 and forms dielectric bar opening 40. After forming the dielectric bar opening 40, the masking layers (i.e., second masking layer 36 and the first masking layer 34) are removed utilizing one or more material removal processes. The removal of the masking layers (i.e., second masking layer 36 and the first masking layer 34) physically exposes the gate cut openings 38 that are located between transistors of the same conductivity type.

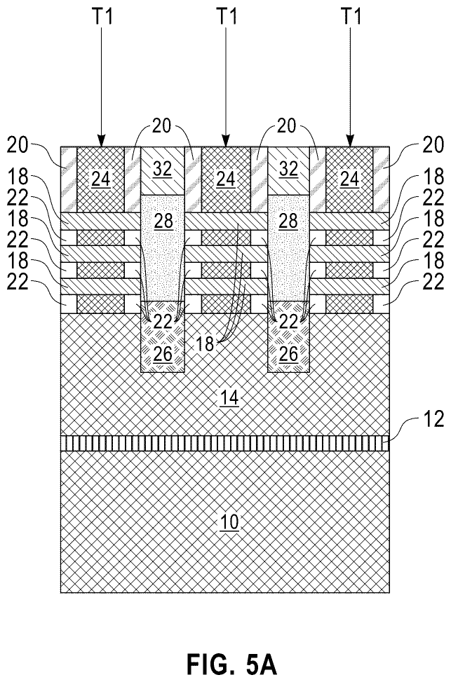

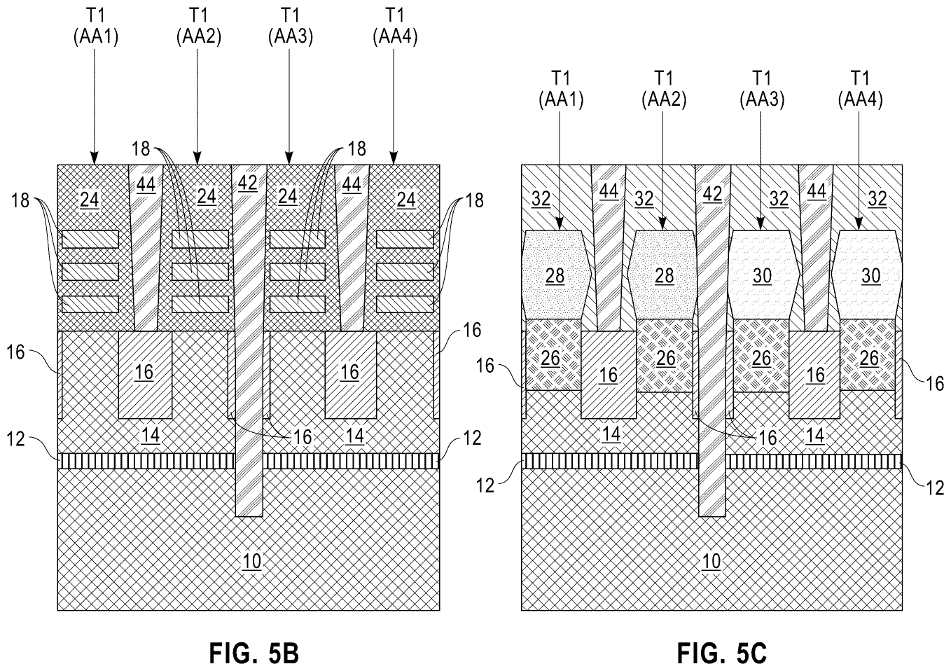

Referring now to FIGS. 5A-5C, there are illustrated the exemplary structure of FIGS. 4A-4C, respectively, after filling each gate cut opening 38 and the dielectric bar opening 40 with a first dielectric structure having a first dielectric constant. In some embodiments of the present application, the first dielectric constant of the first dielectric structure is 10.0 or less, typically the first dielectric constant of the first dielectric structure is from 0.5 to 5.0. The first dielectric structure can include a single first dielectric material (of the first dielectric constant) or multiple first dielectric materials (each of the first dielectric constant) can be used. Illustrative examples of first dielectric materials that can be used in providing the first dielectric structure include, but are not limited to, silicon oxide, Si, SiBCN, SiOCN, SiOC or any combination thereof. When multiple first dielectric materials are employed, the first dielectric structure can include a first dielectric material liner (such as, for example, SiN) and a first dielectric fill material (e.g., silicon oxide) The first dielectric structure is compositionally different from the ILD material that provides the first frontside ILD layer 32 and the trench dielectric material that provides the shallow trench isolation structure 16. The filling each gate cut opening 38 and the dielectric bar opening 40 includes deposition, followed by a planarization process. The deposition of the first dielectric structure in each gate cut opening 38 and the dielectric bar opening 40 can include, for example, CVD, PECVD, PVD, or atomic layer deposition (ALD). Throughout the present application, a planarization process can include, for example, grinding or chemical mechanical planarization (CMP). Each first dielectric structure filled gate cut opening 38 can be referred to as a gate cut pillar 44. The first dielectric structure filled dielectric bar opening 40 can be referred to herein as a dielectric bar 42; the dielectric bar 42 is a precursor structure to the hybrid dielectric bar of the present application. In the present application, each gate cut pillar 44 is used to cut the gate structure 24 between transistors of the same conductivity type, while the dielectric bar 42 is used to cut the gate structure 24 between transistors of different conductivity types.

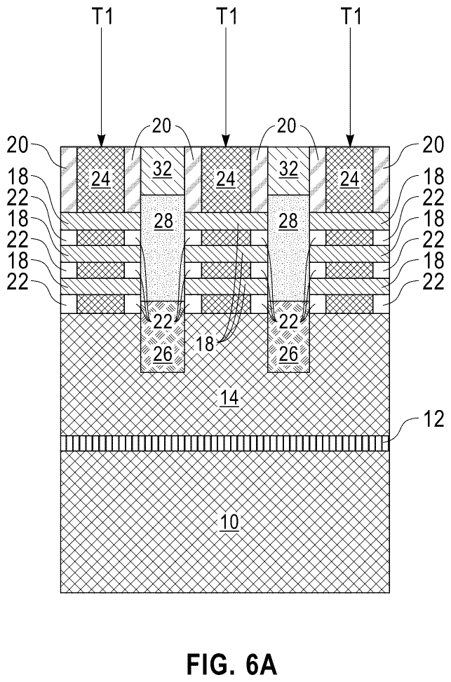

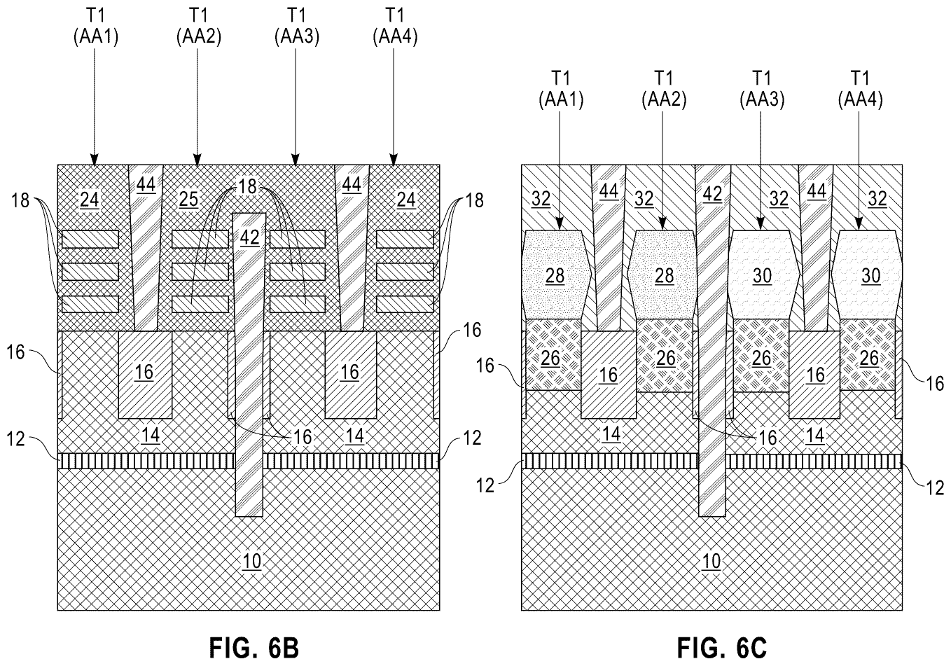

Referring now to FIGS. 6A-6C, there are illustrated the exemplary structure of FIGS. 5A-5C, respectively, after forming a gate connector region (not specifically labeled) above the dielectric bar 42. In the present application, the gate connector region is formed by first recessing the dielectric bar 42 such that a topmost surface of the recessed dielectric bar is located beneath a topmost surface of the gate structure 24 and a topmost surface of the topmost semiconductor channel maternal nanosheets of the first transistors and the second transistors. The recessing includes forming a block mask (not shown) that covers the exemplary semiconductor structure except for the dielectric bar 42. The recessing continues by performing a recess etching process (such as, for example, RIE) that is selective in removing a physically exposed portion of the dielectric bar 42. After recessing, an opening is formed above the now recessed dielectric bar 42. The opening is then filled with a gate conductor (by deposition, followed by planarization) providing the gate connector region mentioned above. The gate conductor used in forming the gate connector region is composed of a same gate electrode material as the gate structure 24. In the drawings, the gate connector region connects the gate structure 24 of the first transistor in the second active device area with the gate structure 24 of the second transistor in the third active device area providing a common, i.e., shared gate structure 25 as illustrated in FIG. 6B. After forming the gate connector region, the block mask is removed providing the exemplary semiconductor structure shown in FIGS. 6A-6C.

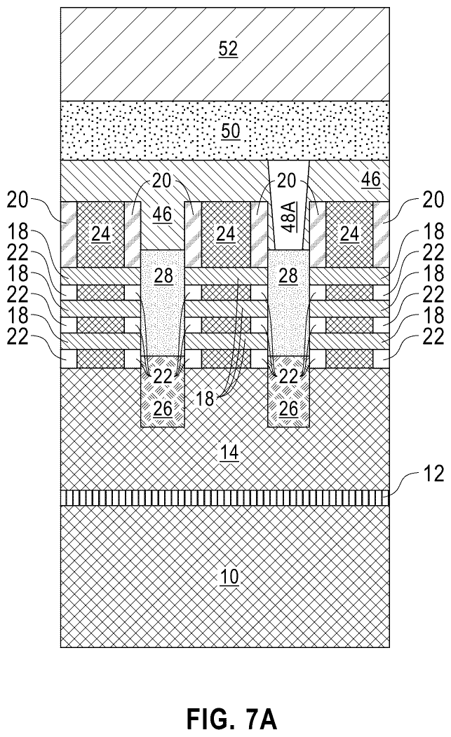

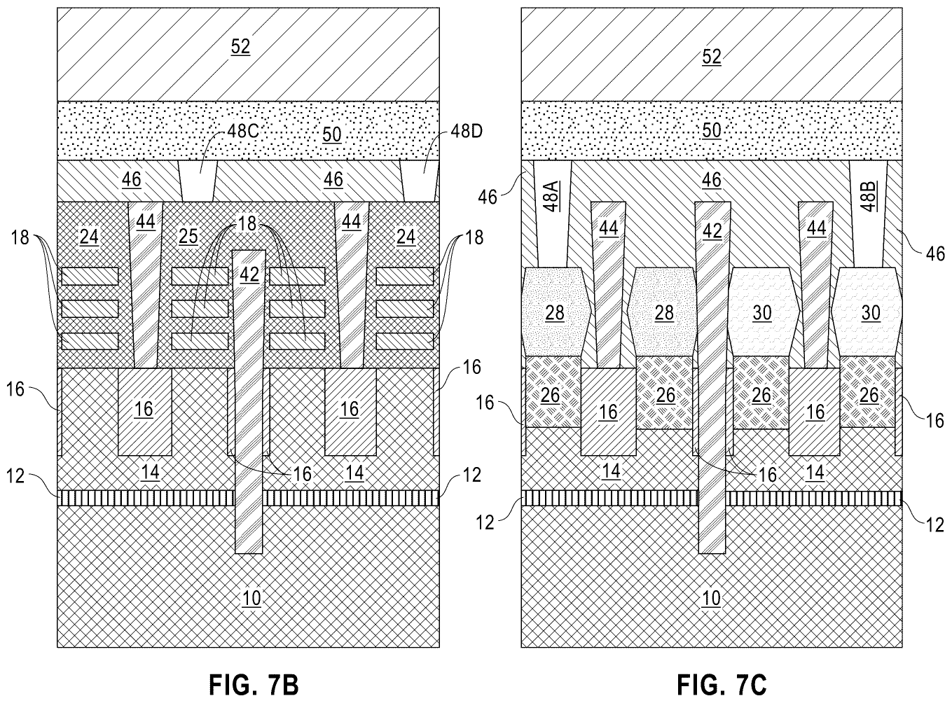

Referring now to FIGS. 7A-7C, there are illustrated the exemplary structure of FIGS. 6A-6C, respectively, after forming a MOL level, a frontside BEOL structure 50, and a carrier wafer 52. The MOL level is formed by first forming a second frontside ILD layer (not specifically labeled in FIGS. 7A-7C) on the exemplary semiconductor structure shown in FIGS. 6A-6C. In some areas of the exemplary structure, the second frontside ILD layer contacts the first frontside ILD layer 32. Collectively, the first frontside ILD layer 32 and the second frontside ILD layer provide a multi-layered MOL structure 46. The second frontside ILD layer can be composed of a compositionally same, or compositionally different, ILD material than the first frontside ILD layer 32. When the first frontside ILD layer 32 and the second frontside ILD layer are composed of a compositionally same ILD material, no material interface is present between the two ILD layers (such an embodiment in illustrated in FIGS. 7A-7C). When the first frontside ILD layer 32 and the second frontside ILD layer are composed of compositionally different ILD materials, a material interface (not shown) is present between the two ILD layers. The second frontside ILD layer can be formed by a deposition process, followed by a planarization process. The MOL level formation continues by forming various frontside contact structures including frontside source/drain contact structures 48A, 48B and frontside gate contact structures 48C, 48D. In the present application, each frontside source/drain contact structure 48A contacts one of the first device source/drain regions 28 of one of the first transistors, while each frontside source/drain contact structure 48B contacts one of the second device source/drain regions 30 of one of the second transistors. In the present application, frontside gate contact structure 48C contacts the shared gate structure 25, while frontside gate contact structure 48D contacts the gate structure 24 of one of the second transistors present in the fourth active device area. Each of the frontside contact structures is composed of at least a contact conductor material. The contact conductor material can include, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. Each of frontside contact structures can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above. Each of the frontside contact structures can be formed by a metallization process which includes forming (by lithography and etching) frontside contact openings in at least some of the ILD layers that provide the MOL multi-layered structure 46, and then filling each frontside contact opening with at least a contact conductor material as defined above. The filling of each frontside contact opening can include a deposition process (such as, for example, CVD, PECVD, atomic layer deposition (ALD) or sputtering), followed by a planarization process.

The frontside BEOL structure 50 is formed on top of the MOL level. The frontside BEOL structure 50 is composed of an interconnect dielectric region having frontside metal wiring embedded therein. The interconnect dielectric region includes one or more interconnect dielectric material layers. The interconnect dielectric material layers can be composed of at least one of the ILD materials mentioned above. The frontside metal wiring can be in the form of metal lines, metal vias, a metal via/metal line combination or any combinations thereof. The frontside metal wiring is composed of an electrically conductive metal or an electrically conductive metal alloy. Exemplary electrically conductive metals include, but are not limited to, Cu, W, Al, Co, or Ru. An exemplary electrically conductive metal alloy is a Cu—Al alloy. The frontside BEOL structure 50 can be formed utilizing any well-known BEOL process including a damascene process or a subtractive metal etch process. It is noted that the frontside BEOL structure 50 is electrically connected to each of the transistors through the frontside contact structures described above.

After forming the frontside BEOL structure 50, carrier wafer 52 is formed on the frontside BEOL structure 50. Carrier wafer 52 can include a semiconductor material as defined above. Carrier wafer 52 is bonded to the frontside BEOL structure 50 utilizing any bonding process that is well known to those skilled in the art. This concludes the frontside processing of the exemplary structure, backside processing will now be performed.

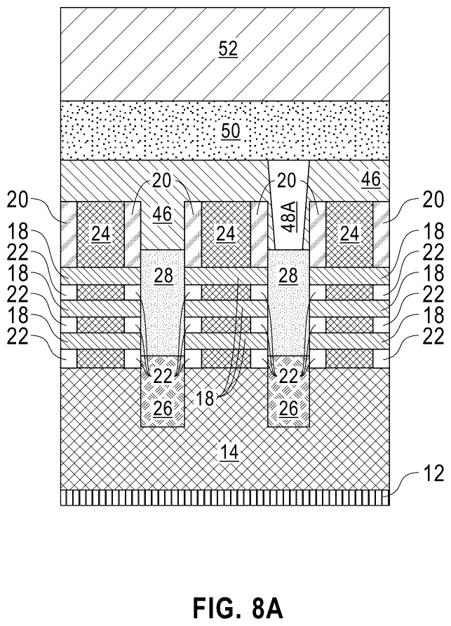

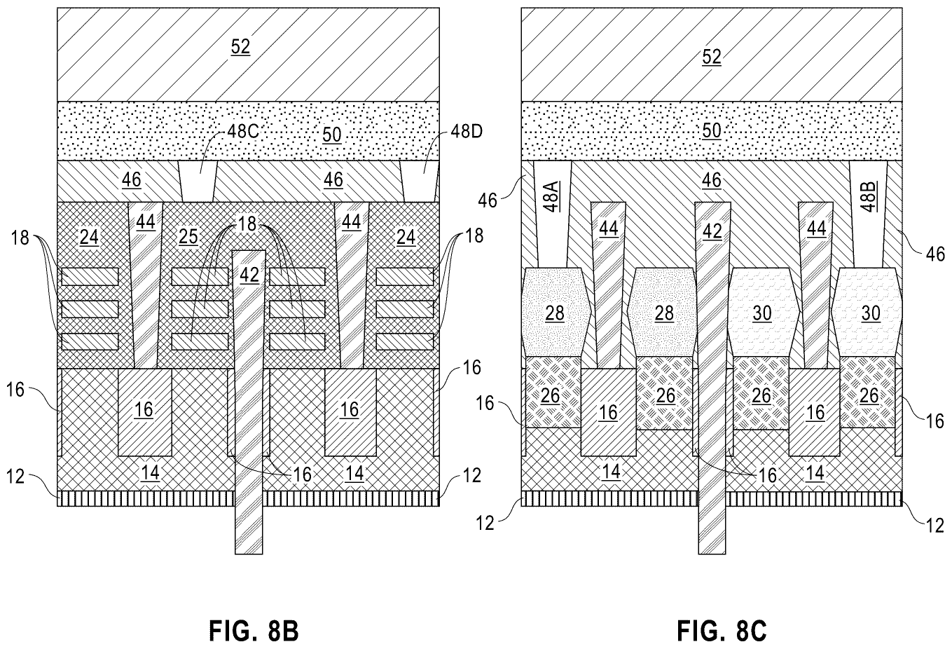

Referring now to FIGS. 8A-8C, there are illustrated the exemplary structure of FIGS. 7A-7C, respectively, after flipping the wafer and removing the semiconductor base layer 10 of the substrate to physically expose an etch stop layer 12 of the structure and a portion of the dielectric bar 42. In the present application, backside processing begins by flipping the exemplary structure 180° to physically expose a backside of the structure. For clarity, the flipping step is not shown in the drawings. Flipping can be performed by hand or by utilizing a mechanical means such as, for example, a robot arm. After flipping, and in the illustrated embodiment, the semiconductor base layer 10 is physically exposed and the physically exposed semiconductor base layer 10 is removed utilizing a material removal process that is selective in removing the semiconductor material that provides the semiconductor base layer 10. The removal of the semiconductor base layer 10 reveals the etch stop layer 12 and a portion of the dielectric bar 42.

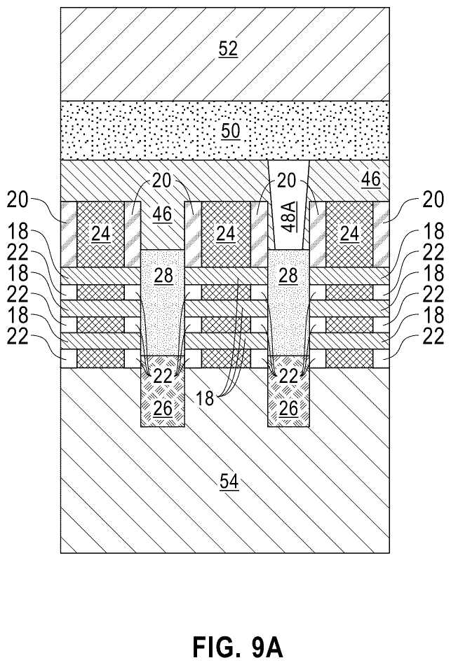

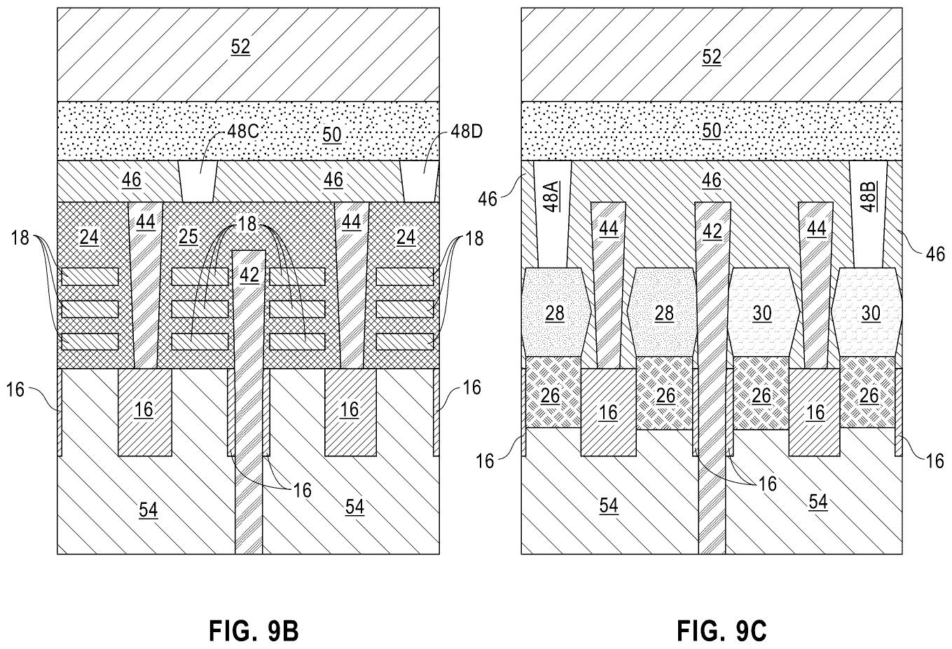

Referring now to FIGS. 9A-9C, there are illustrated the exemplary structure of FIGS. 8A-8C, respectively, after removing the etch stop layer 12 and the semiconductor device layer 14 of the substrate, and forming a backside ILD layer 54. The etch stop layer 12 is removed utilizing a material removal process that is selective in removing the material that provides the etch stop layer 12. The removal of the etch stop layer 12 physically exposes the semiconductor device layer 14. The semiconductor device layer 14 can be removed utilizing a material removal process that is selective in removing the semiconductor device layer 14. The removal of the etch stop layer 12 and the semiconductor device layer 14 physically expose more of the dielectric bar 42 as well as each backside source/drain placeholder structure 26 and each shallow trench isolation structure 16. The backside ILD layer 54 is composed of an ILD material as mentioned above for the first frontside ILD layer 32. The backside ILD layer 54 can be formed by deposition, followed by planarization. As is shown in FIGS. 9A-9C, the planarization stops on a surface of dielectric bar 42 such that the dielectric bar 42 has a physically exposed surface on the backside of the semiconductor structure. The backside ILD layer 54 contacts physically exposed surfaces of each backside source/drain placeholder structure 26 and each shallow trench isolation structure 16. The backside ILD layer 54 also contacts a sidewall of a lower portion of the dielectric bar 42 that is present on the backside of the structure.

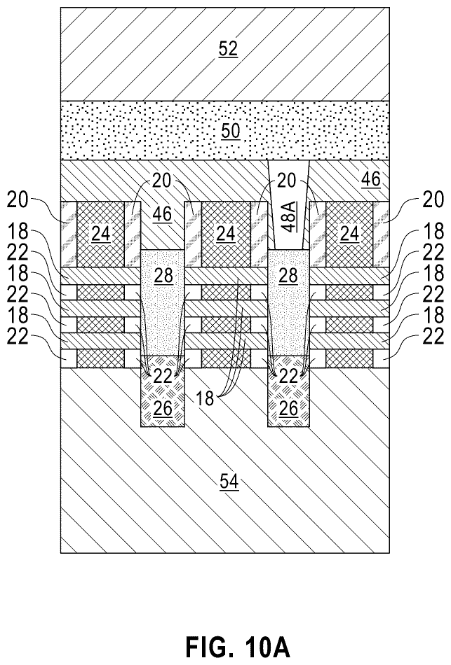

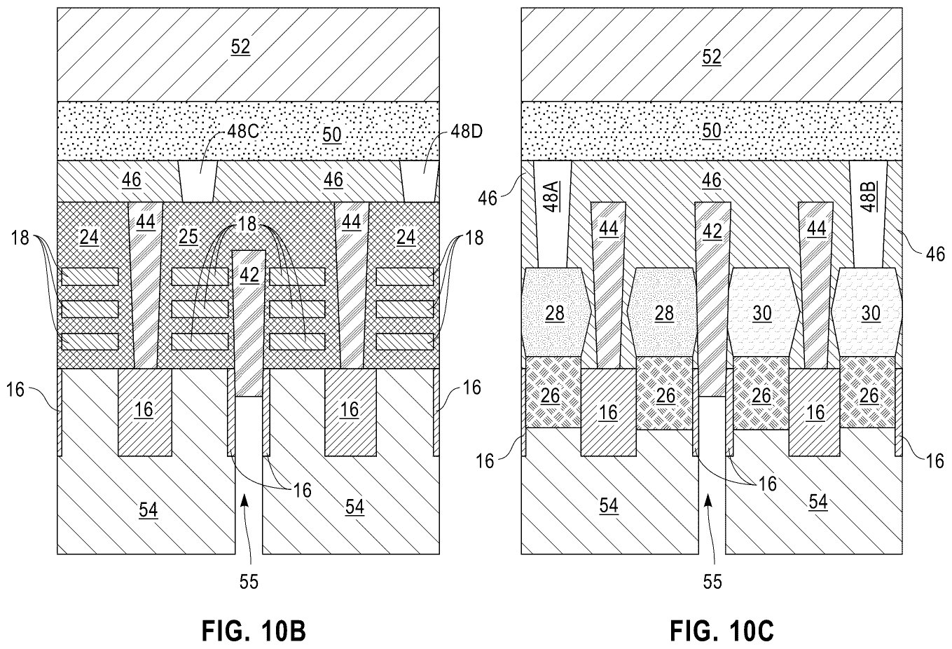

Referring now to FIGS. 10A-10C, there are illustrated the exemplary structure of FIGS. 9A-9C, respectively, after recessing a lower portion of dielectric bar 42 to provide a backside bar opening 55. The backside bar opening 55 extends through the backside ILD layer 54 and partially through the shallow trench isolation structure 16 that is located between the different conductivity type transistors that are located in the second active device area and the third active device area. The recessing of the lower portion of dielectric bar 42 includes a recess etching process (such as, for example, RIE) that is selective in removing a physically exposed portion of the dielectric bar 42.

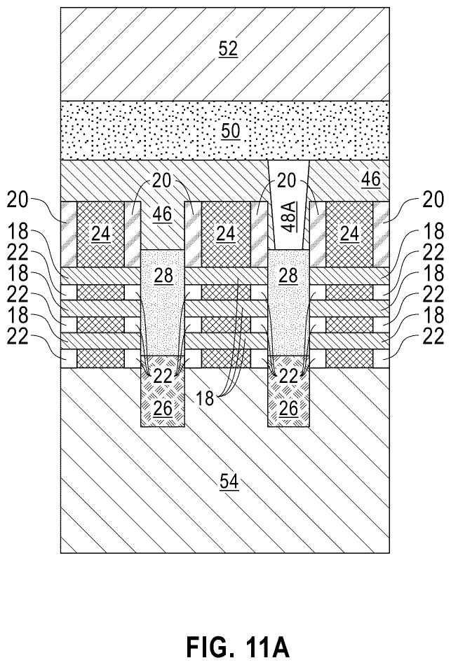

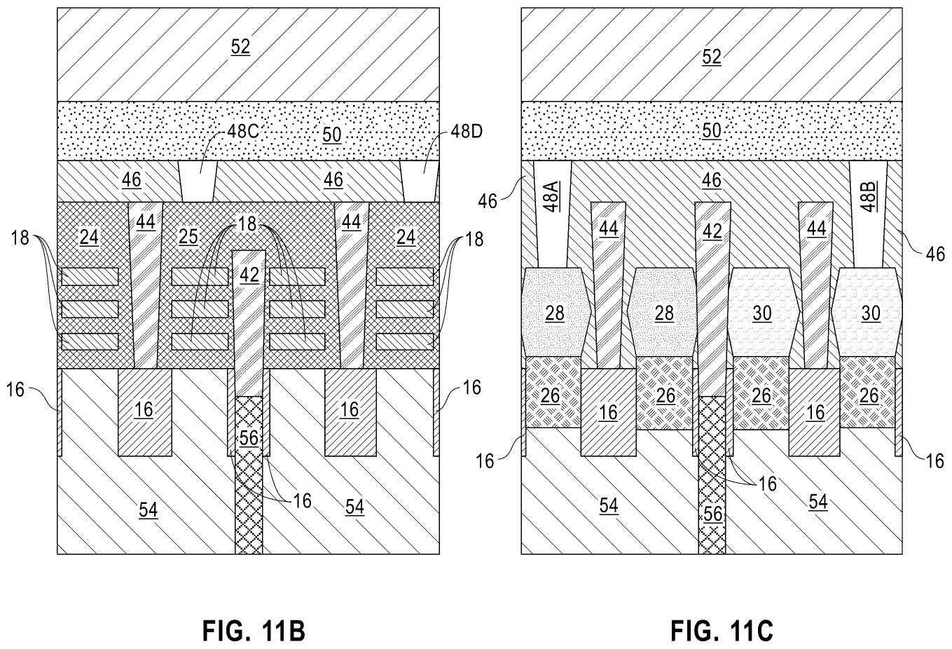

Referring now to FIGS. 11A-11C, there are illustrated the exemplary structure of FIGS. 10A-10C, respectively, after forming a second dielectric structure 56 having a second dielectric constant that is greater than the first dielectric constant in the backside bar opening 55. The second dielectric structure 56 extends through the backside ILD layer 54 and partially through the shallow trench isolation structure 16 that is located between the different conductivity type transistors that are located in the second active device area and the third active device area. The second dielectric structure also contacts the first dielectric structure of the dielectric bar 42. Collectively, the remaining portion of the first dielectric bar 42 (composed entirely of the first dielectric structure) and the second dielectric structure 56 form a hybrid dielectric bar in accordance with the present application. Stated in other terms, the hybrid dielectric bar includes an upper portion composed of the first dielectric structure (represented by dielectric bar 42 shown in FIGS. 11B and 11C) and a lower portion composed of the second dielectric structure 56. In some embodiments of the present application, the second dielectric constant is 7.0 or greater, typically the second dielectric constant is from 8.0 to 20. The second dielectric structure 56 can be composed of a single second dielectric material (having the second dielectric constant) or multiple second dielectric materials (each having the second dielectric constant). Illustrative examples of second dielectric materials that have the second dielectric constant include, but are not limited to, hafnium oxide or aluminum oxide. When multiple second dielectric materials are employed, the second dielectric structure 56 may include a second dielectric material liner and a second dielectric fill material. The second dielectric structure 56 is compositionally different from the ILD material that provides the first dielectric structure, the backside ILD layer 54 and the trench dielectric material that provides the shallow trench isolation structure 16. The second dielectric structure 56 is formed into the backside bar opening 55 by deposition, followed by a planarization process. The second dielectric structure 56 has a surface that is substantially coplanar with a horizontal surface of the backside ILD layer 54. It is noted that in the present application, each gate cut pillar 44 has a topmost surface that is vertically offset and is located above a topmost surface of the hybrid dielectric bar. The presence of the second dielectric structure 56 in the hybrid dielectric bar of the present application increases decoupling capacitance in the semiconductor device.

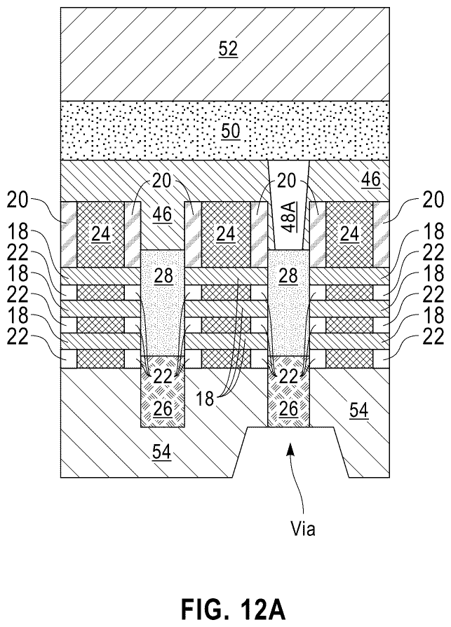

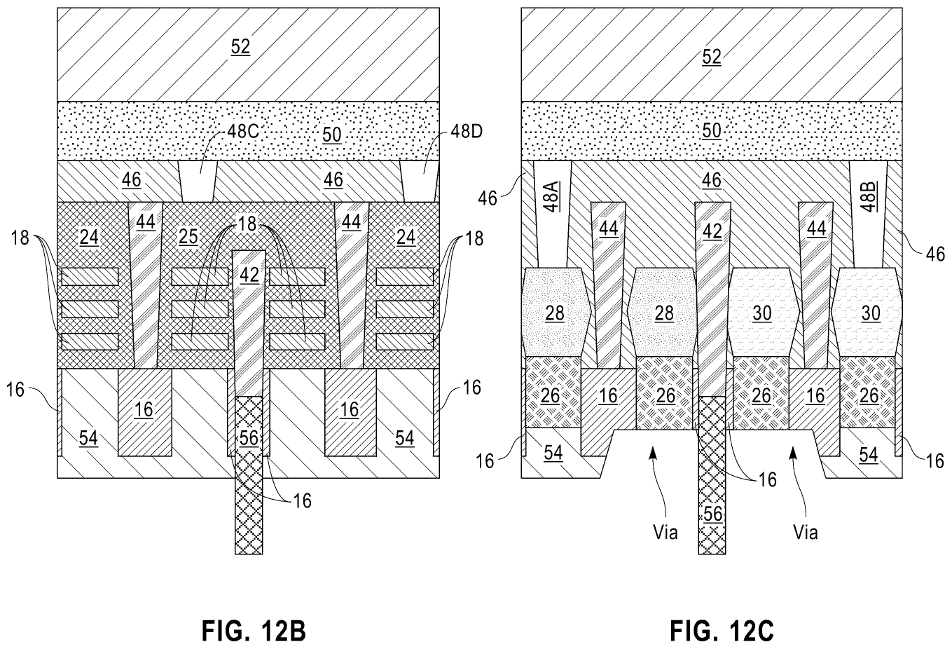

Referring now to FIGS. 12A-12C, there are illustrated the exemplary structure of FIGS. 11A-11C, respectively, after patterning the backside ILD layer 54 to provide a trench opening (not specifically labeled) and a backside contact vias (“Via”). The trench opening is connected to the back side contact vias and it would be located beneath the patterned backside ILD layer 54 shown in FIGS. 12A-12C. The patterning of the backside ILD layer 54 includes a lithographic patterning process as mentioned above in which at least a patterned photoresist (not shown) is formed on the backside ILD layer 54. An etch such as, for example, RIE, is then used to transfer the pattern present in the patterned photoresist into the underlying backside ILD layer 54. The vias physically expose some of the backside source/drain contact placeholder structure 26 and a lower portion of the hybrid dielectric bar. Notably, a lower portion of the second dielectric structure 56 of the hybrid dielectric bar is physically exposed as shown in FIGS. 12B and 12C. After transferring the pattern into the backside ILD layer 54, the patterned photoresist can be removed used a conventional resist removal process such as, for example, ashing. Due to the hybrid dielectric bar being present in the backside of the structure, the patterning of the backside ILD layer 54 becomes easier at tight spacing between the different conductivity type transistors.

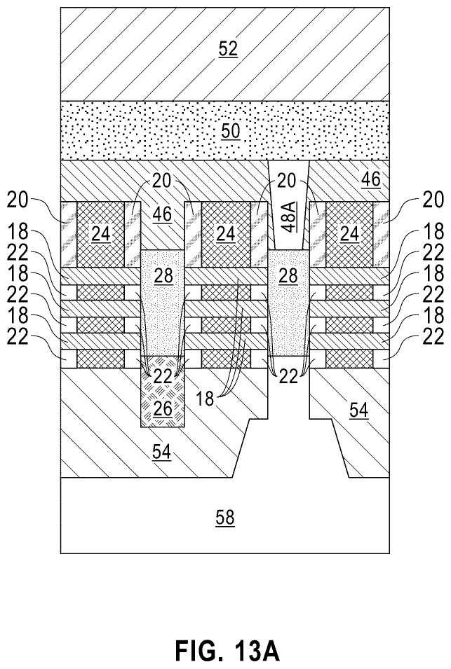

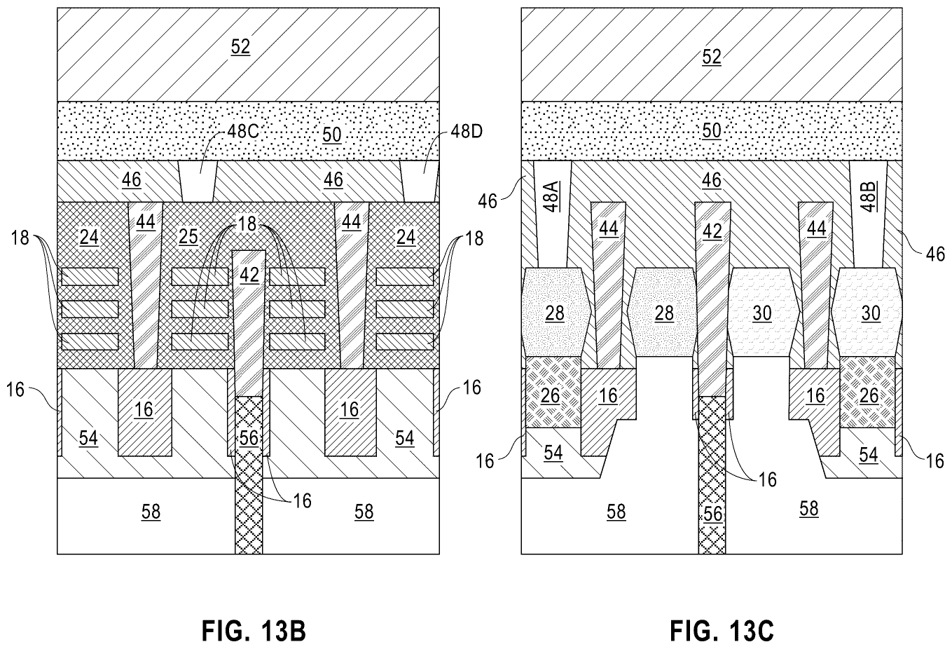

Referring now to FIGS. 13A-13C, there are illustrated the exemplary structure of FIGS. 12A-12C, respectively, after physically exposing one of the first device source/drain region 28 of the first transistor and one of the second device source/drain regions 30 of the second transistor, and forming a backside contact conductor material layer 58. The physically exposing the first device source/drain region 28 and the second device source/drain region 30 includes removing the backside source/drain contact placeholder structure 26 that are physically exposed during via formation as shown in FIGS. 12A-12C. The backside source/drain contact placeholder structure 26 that are physically exposed can be removed utilizing a material removal process that is selective in removing the semiconductor material that provides the backside source/drain contact placeholder structure 26. Next, the backside contact conductor material layer 58 is formed. The backside contact conductor material layer 58 is composed at least a contact conductor material as defined above for the frontside contact structures. The backside contact conductor material layer 58 can also include one or more contact liners (not shown). In one or more embodiments, the contact liner (not shown) can include a diffusion barrier material as defined above. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above. The backside contact conductor material layer 58 can be formed by a deposition process such as, for example, CVD, PECVD, ALD or sputtering, followed by a planarization process. As is shown, the backside contact conductor material layer 58 is in contact with the first device source/drain region 28 and the second device source/drain region 30 and contacts a sidewall of the second dielectric structure 56 of the hybrid dielectric bar.

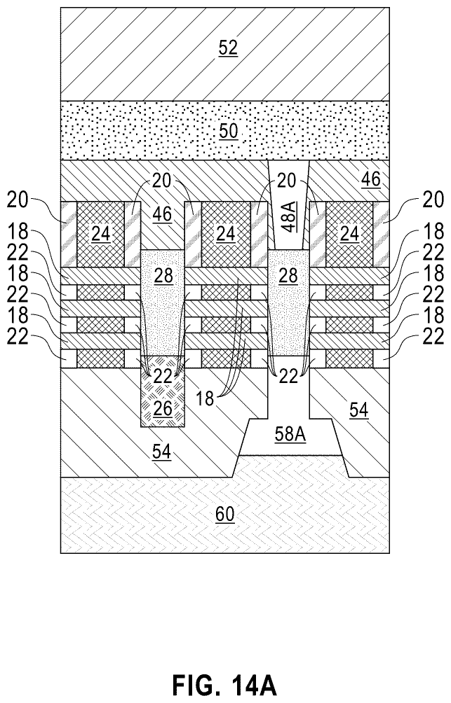

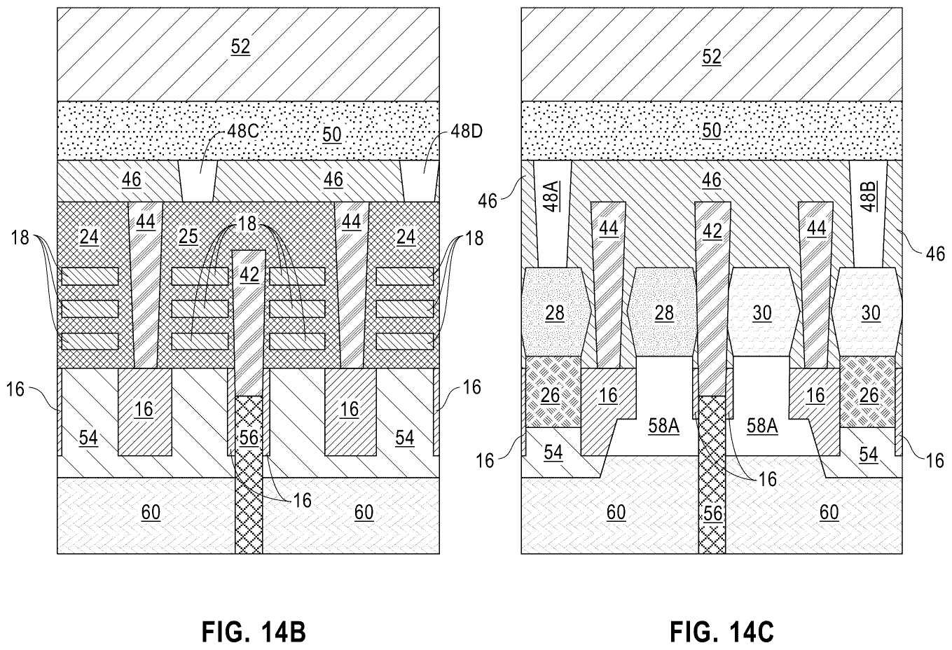

Referring now to FIGS. 14A-14C, there are illustrated the exemplary structure of FIGS. 13A-13C, respectively, after recessing the backside contact conductor material layer 58 and forming a backside power rail material layer 60. The recessing of the backside contact conductor material layer 58 includes a recess etching process that is selective in removing the backside contact conductor material layer 58. A portion of the backside contact conductor material layer 58 remains and is referred to herein as a backside source/drain contact structure 58A. As is shown, one of the backside source/drain contact structures 58A contacts the first device source/drain region 28, while another of the backside source/drain contact structures 58A contacts the second device source/drain region 30. The backside power rail material layer 60 is composed of an electrically conductive power line material. The electrically conductive power line material is selected to have a lower resistivity than the contact conductor material that is used in providing the backside contact conductor material layer 58. The electrically conductive power line material includes, but is not limited to, W, Co, Ru, Al, Cu, Pt, Rh, or Pd. A thin metal adhesion layer, such as TiN, TaN, etc. can be also formed along a sidewall and bottom surface of the backside power rail material layer 60. The backside power rail material layer 60 can be formed by a deposition process such as, for example, CVD, PECVD, ALD or sputtering. A planarization process can follow the deposition process. The backside power rail material layer 60 has a bottommost surface that is substantially coplanar with a bottommost surface of the second dielectric structure 56 of the hybrid dielectric bar. As is shown, the backside power rail material layer 60 and the backside source/drain contact structures 58A are in contact with a sidewall of a lower portion of the second dielectric structure 56 of the hybrid dielectric bar; an upper portion of the second dielectric structure contacts the shallow trench isolation structure 16 that is located between the active device areas including the different conductivity type transistors.

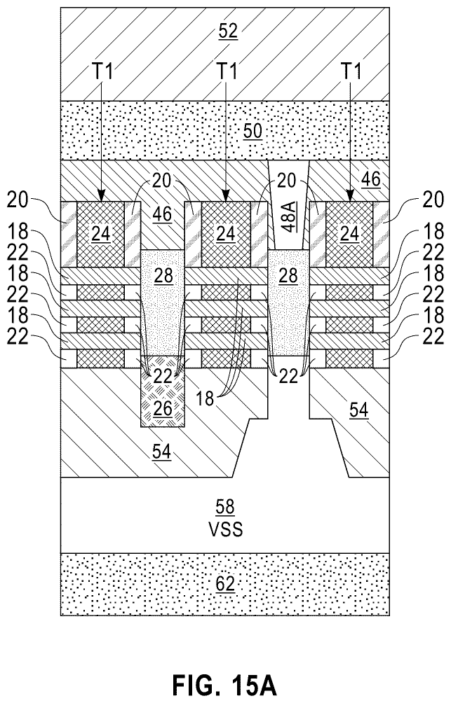

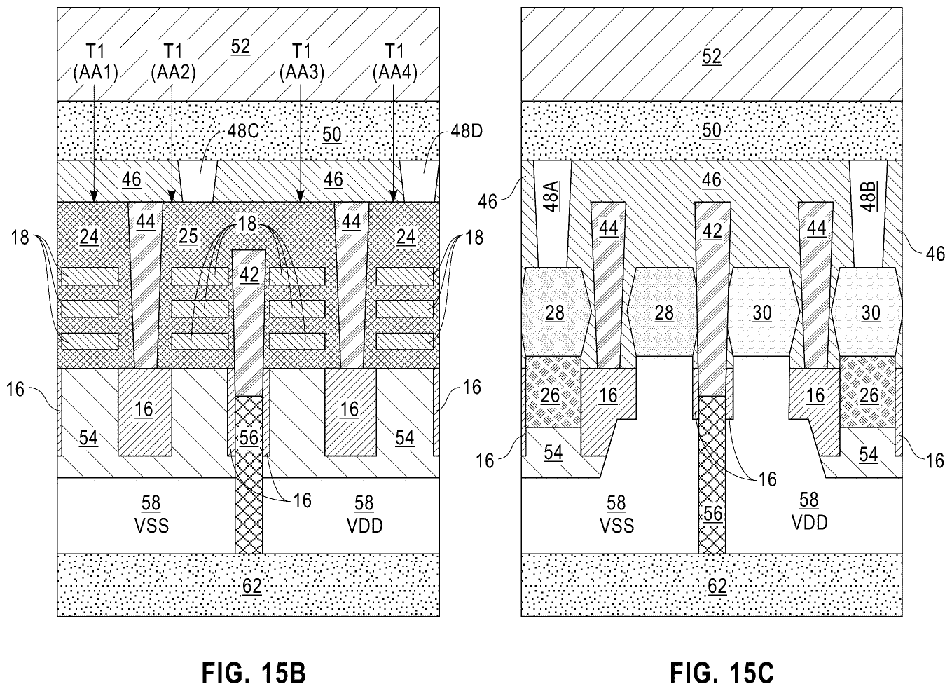

Referring now to FIGS. 15A-15C, there are illustrated the exemplary structure of FIGS. 13A-13C, respectively, after forming a backside BEOL structure 62 on the backside contact conductor material layer 58. The backside BEOL structure 62 (which can deliver power from the backside of the device) is composed of an interconnect dielectric region having backside metal wiring embedded therein. The interconnect dielectric region includes one or more interconnect dielectric material layers. The interconnect dielectric material layers can be composed of one of the ILD materials mentioned above. The backside metal wiring which can be in the form of metal lines, metal vias, a metal via/metal line combination or any combinations thereof is composed of an electrically conductive metal or an electrically conductive metal alloy, as both defined above. The backside BEOL structure 62 can be formed utilizing any well-known BEOL process including a damascene process or a subtractive metal etch process. In the illustrated embodiment, the backside BEOL structure 62 is electrically contacted to the source/drain regions of the different conductivity type transistors by the backside contact conductor material layer 58. As is further shown, the bottommost surface of the second dielectric structure 56 lands on the backside BEOL structure 62. In FIGS. 15A-15C, the terms “VDD” and “VSS” are shown in parentheses. VDD stands for a positive supply voltage, while VSS stands for a ground or reference voltage. The designations are including in the drawings to show the location of these different volage levels.

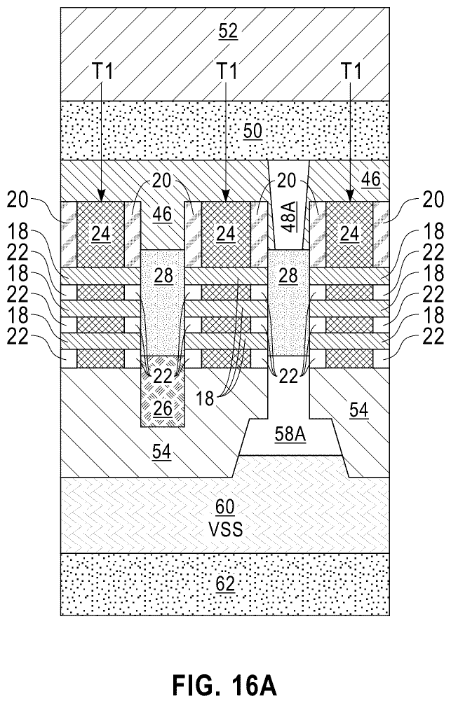

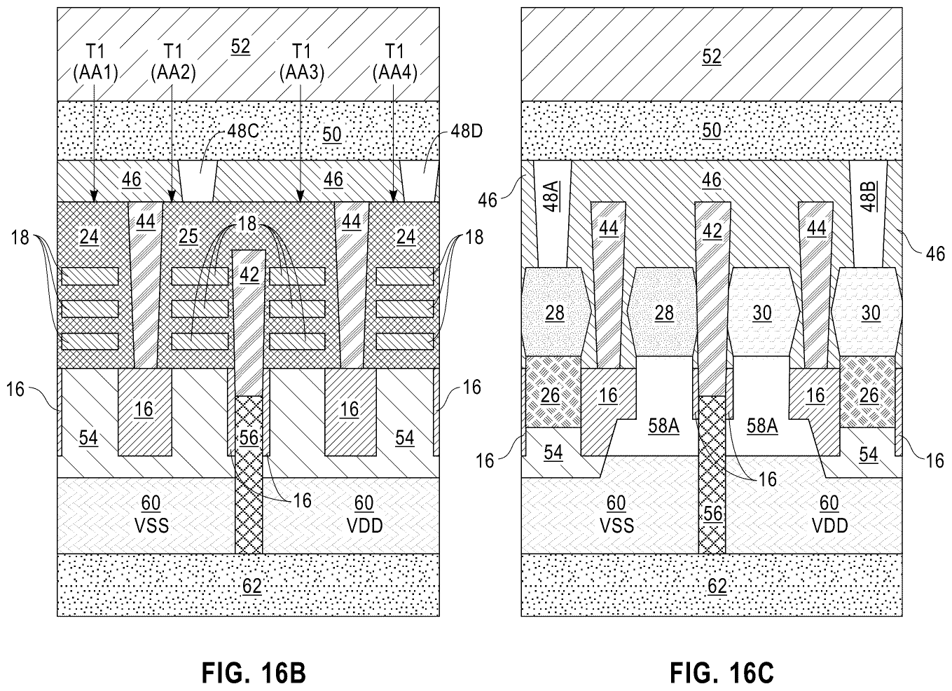

Referring now to FIGS. 16A-16C, there are illustrated the exemplary structure of FIGS. 14A-14C, respectively, after forming backside BEOL structure 62 on the backside power rail material layer 60. The backside BEOL structure 62 of this embodiment is the same as that described above in FIGS. 15A-15C. In the illustrated embodiment, the backside BEOL structure 62 is electrically contacted to the source/drain regions of the different conductivity type transistors by the backside power rail material layer 60 and one of the backside contact structures 58A. As is further shown, the bottommost surface of the second dielectric structure lands on the backside BEOL structure 62. In FIGS. 16A-16C, the terms “VDD” and “VSS” are shown in parentheses.

Notably, FIGS. 15A-15C and 16A-16C illustrate a semiconductor device in accordance with an embodiment of the present application. Notably, FIGS. 15A-15C and 16A-16C illustrate a semiconductor device that includes hybrid dielectric bar present between a first transistor of a first conductivity type (e.g., T1 located in AA2) and a second transistor of a second conductivity type (e.g., T2 located in AA3) that is different from the first conductivity type. The hybrid dielectric bar includes an upper portion composed of first dielectric structure (i.e., dielectric bar 42) having a first dielectric constant and a lower portion composed of second dielectric structure 56 having a second dielectric constant in which the second dielectric constant is greater than the first dielectric constant. The semiconductor device further includes backside BEOL structure 62 electrically connected to a first device source/drain region 28 of the first transistor and to a second device source/drain region 30 of the second transistor. As is illustrated, the hybrid dielectric bar is in contact with the backside BEOL structure 62. The semiconductor device also includes frontside BEOL structure 50 electrically connected to both the first transistor and second transistor.

FIGS. 15A-15C and 16A-16C illustrate a semiconductor device in accordance with another embodiment of the present application. Notably, FIGS. 15A-15C and 16A-16C illustrate a semiconductor device includes a first active device area including a first set of first transistors of a first conductivity type (i.e., T1 located in AA1), a second active device area located adjacent to the first active device area and including a second set of first transistors of the first conductivity type (i.e., T1 located in AA2), a third active device area located adjacent to the second active device area and including a first set of second transistors of a second conductivity type (i.e., T2 located in AA3) that is different from the first conductivity type, and a fourth active device area located adjacent to the third active device area and including a second set of second transistors of the second conductivity type (i.e., T2 located in AA4). The semiconductor device of this embodiment further includes a hybrid dielectric bar present between the second set of first transistors and the first set of second transistors. The hybrid dielectric bar includes an upper portion composed of first dielectric structure (i.e., dielectric bar 42) having a first dielectric constant and a lower portion composed of second dielectric structure 56 having a second dielectric constant in which the second dielectric constant is greater than the first dielectric constant. The semiconductor device further includes a first gate cut pillar (i.e., the first gate cut pillar 44 from the left hand side of FIGS. 15B-15C and 16B-16C) located between the first set of first transistors and the second set of first transistors, and a second gate cut pillar (i.e., the second gate cut pillar 44 from the left hand side of FIGS. 15B-15C and 16B-16C) located between the first set of second transistors and the second set of second transistors in which the first gate cut pillar and the second gate cut pillar are composed entirely of the first dielectric structure.

In one embodiment and as shown in FIGS. 16A-16C, the lower portion of the hybrid dielectric bar (i.e., the second dielectric structure 56) separates a VSS backside power rail from a VDD backside power rail. In such an embodiment, the VSS backside power rail is located directly on the backside BEOL structure 62, and is electrically connected to the first device source/drain region 28 of the first transistor by a first backside source/drain contact structure (i.e., the backside source/drain contact structure 58A shown on the left hand side of FIG. 16C) and the VDD backside power rail is located directly on the backside BEOL structure 62 and is electrically connected to the second device source/drain region 30 of the second transistor by a second backside source/drain contact structure (i.e., the backside source/drain contact structure 58A shown on the left hand side of FIG. 16C).

In another embodiment and as shown in FIGS. 15A-15C, the lower portion of the hybrid dielectric bar (i.e., the second dielectric structure 56) separates a VSS backside contact conductor material layer from a VDD backside contact conductor material layer. In such an embodiment, the VSS backside contact conductor material layer is located directly on the backside BEOL structure 62, and is electrically connected directly to the first device source/drain region 28 of the first transistor and the VDD backside contact conductor material layer is located directly on the backside BEOL structure 62 and is electrically connected directly to the second device source/drain region 30 of the second transistor.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a hybrid dielectric bar present between a first transistor of a first conductivity type and a second transistor of a second conductivity type that is different from the first conductivity type, wherein the hybrid dielectric bar comprises an upper portion composed of a first dielectric structure having a first dielectric constant and a lower portion composed of a second dielectric structure having a second dielectric constant, wherein the second dielectric constant is greater than the first dielectric constant; and
a backside back-end-of-the-line (BEOL) structure electrically connected to a first device source/drain region of the first transistor and to a second device source/drain region of the second transistor, wherein the hybrid dielectric bar contacts the backside BEOL structure.

2. The semiconductor device of claim 1, further comprising a frontside BEOL structure electrically connected to both the first transistor and the second transistor.

3. The semiconductor device of claim 1, wherein the hybrid dielectric bar passes through, and is in contact with, a shallow trench isolation structure that is located between the first transistor and the second transistor.

4. The semiconductor device of claim 1, wherein the first transistor and the second transistor share a common gate structure.

5. The semiconductor device of claim 4, wherein the common gate structure extends over a topmost surface of the hybrid dielectric bar.

6. The semiconductor device of claim 1, wherein the lower portion of the hybrid dielectric bar separates a VSS backside power rail from a VDD backside power rail.

7. The semiconductor device of claim 6, wherein the VSS backside power rail is located directly on the backside BEOL structure and is electrically connected to the first device source/drain region of the first transistor by a first backside source/drain contact structure, and the VDD backside power rail is located directly on the backside BEOL structure and is electrically connected to the second device source/drain region of the second transistor by a second backside source/drain contact structure.

8. The semiconductor device of claim 1, wherein the lower portion of the hybrid dielectric bar separates a VSS backside contact conductor material layer from a VDD backside contact conductor material layer.

9. The semiconductor device of claim 8, wherein the VSS backside contact conductor material layer is located directly on the backside BEOL structure, and is electrically connected directly to the first device source/drain region of the first transistor and the VDD backside contact conductor material layer is located directly on the backside BEOL structure and is electrically connected directly to the second device source/drain region of the second transistor.

10. The semiconductor device of claim 1, further comprising a gate cut pillar located adjacent to the first transistor wherein the gate cut pillar has a topmost surface that is vertically offset and is located above a topmost surface of the hybrid dielectric bar.

11. The semiconductor device of claim 10, wherein the gate cut pillar is composed entirely of the first dielectric structure.

12. A semiconductor device comprising:
a first active device area comprising a first set of first transistors of a first conductivity type;
a second active device area located adjacent to the first active device area and comprising a second set of first transistors of the first conductivity type;
a third active device area located adjacent to the second active device area and comprising a first set of second transistors of a second conductivity type that is different from the first conductivity type;
a fourth active device area located adjacent to the third active device area and comprising a second set of second transistors of the second conductivity type;
a hybrid dielectric bar present between the second set of first transistors and the first set of second transistors, wherein the hybrid dielectric bar comprises an upper portion composed of a first dielectric structure having a first dielectric constant and a lower portion composed of a second dielectric structure having a second dielectric constant, wherein the second dielectric constant is greater than the first dielectric constant;
a first gate cut pillar located between the first set of first transistors and the second set of first transistors; and
a second gate cut pillar located between the first set of second transistors and the second set of second transistors, wherein the first gate cut pillar and the second gate cut pillar are composed entirely of the first dielectric structure.

13. The semiconductor device of claim 12, further comprising a backside back-end-of-the-line (BEOL) structure electrically connected to a first device source/drain region of one of first transistors of the second set of first transistors and to a second device source/drain region of one of the second transistors of the first set of second transistors, and a frontside BEOL structure electrically connected to the first set of first transistors, the second set of first transistors, the first set of second transistors, and the second set of second transistors, wherein the hybrid dielectric bar contacts the backside BEOL structure.

14. The semiconductor device of claim 12, wherein the hybrid dielectric bar passes through, and is in contact with, a shallow trench isolation structure that is located between the second set of first transistor and the first set of second transistors.

15. The semiconductor device of claim 12, wherein the first transistor of the second set of first transistors and the second transistor of the first set of second transistors share a common gate structure, and the common gate structure extends over a topmost surface of the hybrid dielectric bar.

16. The semiconductor device of claim 13, wherein the lower portion of the hybrid dielectric bar separates a backside source/drain contact structure from a VSS backside power rail and a VDD backside power rail.

17. The semiconductor device of claim 16, wherein the VSS backside power rail is located directly on the backside BEOL structure and is electrically connected to the first device source/drain region of the first transistor by a first backside source/drain contact structure, and the VDD backside power rail is located directly on the backside BEOL structure and is electrically connected to the second device source/drain region of the second transistor by a second backside source/drain contact structure.

18. The semiconductor device of claim 13, wherein the lower portion of the hybrid dielectric bar separates a VSS backside contact conductor material layer from a VDD backside contact conductor material layer.

19. The semiconductor device of claim 18, wherein the VSS backside contact conductor material layer is located directly on the backside BEOL structure, and is electrically connected directly to the first device source/drain region of the first transistor and the VDD backside contact conductor material layer is located directly on the backside BEOL structure and is electrically connected directly to the second device source/drain region of the second transistor.

20. The semiconductor device of claim 12, wherein each of the first gate cut pillar and the second gate cut pillar has a topmost surface that is vertically offset and is located above a topmost surface of the hybrid dielectric bar.
